(19) United States
(12) Patent Application Publication
(10) Pub. No.: US 2012/0146063 A1
(43) Pub. Date: Jun. 14, 2012

(54) LIGHT EMITTING DIODE LAMP

(75) Inventor: KUO-CHENG CHANG, Chu-Nan (TW)

(73) Assignee: FOXSEMICON INTEGRATED TECHNOLOGY, INC., Chu-Nan (TW)

(21) Appl. No.: 13/304,395

(22) Filed: Nov. 24, 2011

(30) Foreign Application Priority Data
Dec. 8, 2010 (TW) 099142713

(51) Int. Cl. H01L 27/15

(52) U.S. Cl. 257/88; 257/E27.12

(57) ABSTRACT

An LED lamp comprises a front cover comprising an upper plate, a first sidewall perpendicular to the upper plate, a through hole in a central portion of the upper plate; a rear cover comprising a bottom plate, a second sidewall perpendicular from the bottom plate to engage the front and rear covers by sleeving over the first sidewall; a lamp body comprising a first and second substrates, a third sidewall interconnecting the first and second substrates, the third sidewall penetrating through the through hole and is between the upper and bottom plates; a first LED unit on the first substrate, facing the second substrate; a second LED unit on the second substrate, facing away the first substrate, wherein the LED lamp is configure to direct light from the first LED units via the third sidewall, and light from the second LED units along a direction away from the first substrate.

### TECHNICAL FIELD

The disclosure generally relates to a light emitting diode lamp.

### DESCRIPTION OF RELATED ART

In recent years, due to excellent light quality and high luminous efficiency, light emitting diodes (LEDs) have increasingly been used as substitutes for incandescent bulbs, compact fluorescent lamps, or fluorescent tubes as light sources of illumination devices.

In conventional LED lamp, LED units are generally arranged on a common substrate and all of the LED units emit light along a same direction. Thus, all of the LED units illuminate a predetermined area in a same manner and a light intensity of the LED lamp is not adjustable. The LED lamp must be replaced to obtain a different lighting distribution.

Therefore, an improved LED lamp is desired to overcome the above described shortcomings

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric, assembled view of an LED lamp in accordance with one embodiment of the present disclosure.

FIG. 2 is an exploded view of the LED lamp in FIG. 1.

FIG. 3 is an exploded view of the LED lamp in FIG. 1, shown in another aspect.

FIG. 4 is a cross-section of a lamp body of the LED lamp in FIG. 1.

### DETAILED DESCRIPTION

An embodiment of an LED lamp will now be described in detail below and with reference to the drawings.

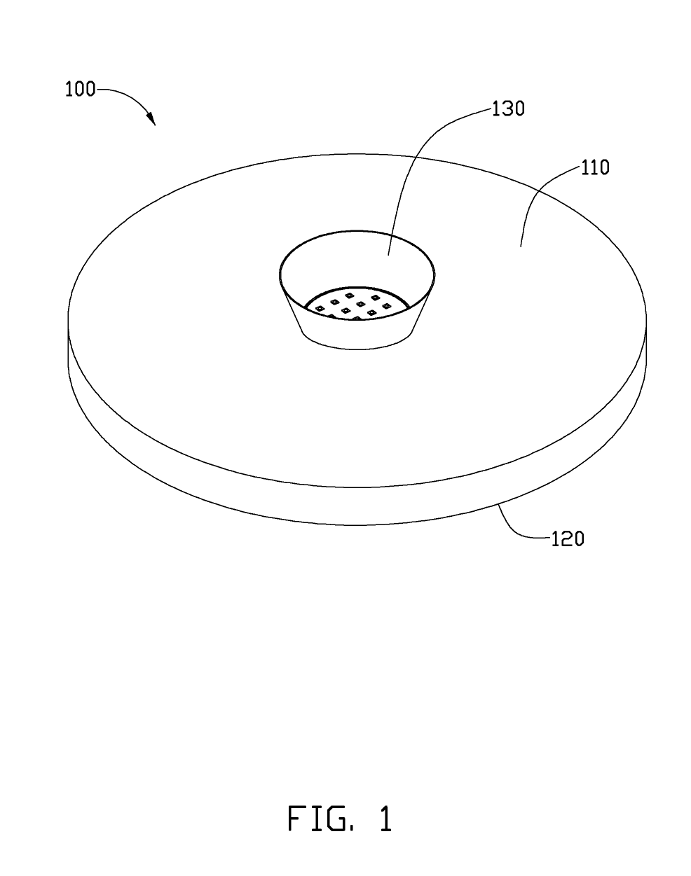

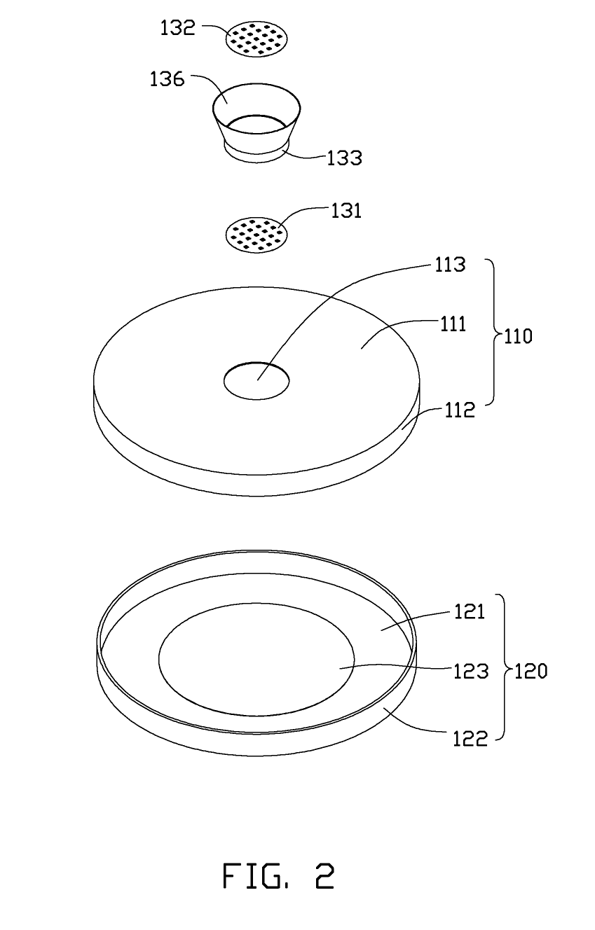

Referring to FIGS. 1-2, an LED lamp 100 in accordance with an embodiment comprises a front cover 110, a rear cover 120, and a lamp body 130.

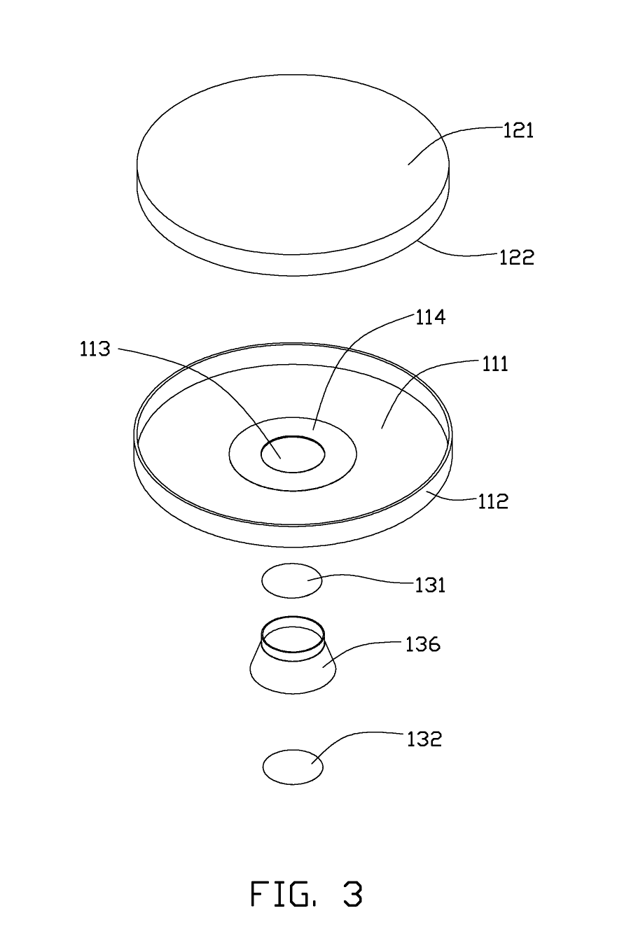

Referring also to FIG. 3, the front cover 110 comprises an upper plate 111, and a first sidewall 112 extending downwardly and perpendicularly from the upper plate 111. A through hole 113 is defined in a central portion of the upper plate 111. A first reflective plate 114 is formed on a bottom surface of the upper plate 111 facing towards the rear cover 120. In this embodiment, the first reflective plate 114 is annular and surrounds the through hole 113. The front cover 110 is made of a material selected from a group consisting of glass, polycarbonate (PC) and polymethyl methacrylate (PMMA). In alternative embodiments, the first reflective plate 114 can be a metallic reflective layer coated on the bottom surface of the upper plate 111 facing towards the rear cover 120. The metallic reflective layer can be made of a material selected from a group consisting of Ag, Ni, Al, Cu, Au, and alloy thereof.

The rear cover 120 comprises a bottom plate 121, and a second sidewall 122 extending upwardly and perpendicularly from the bottom plate 121. The second sidewall 122 is sleeved on the first sidewall 112 of the front cover 110 to engage the front cover 110 and the rear cover 120. The upper plate 111 is parallel to the bottom plate 121. A second reflective plate 123 is formed on an upper surface of the bottom plate 121 facing towards the front cover 110. The rear cover 120 can be made of a material selected from a group consisting of glass, polycarbonate and polymethyl methacrylate. In alternative embodiments, the second reflective plate 123 can be a metallic reflective layer coated on the upper surface of the bottom plate 121 facing towards the front cover 110. The metallic reflective layer can be made of a material selected from a group consisting of Ag, Ni, Al, Cu, Au, and alloy thereof.

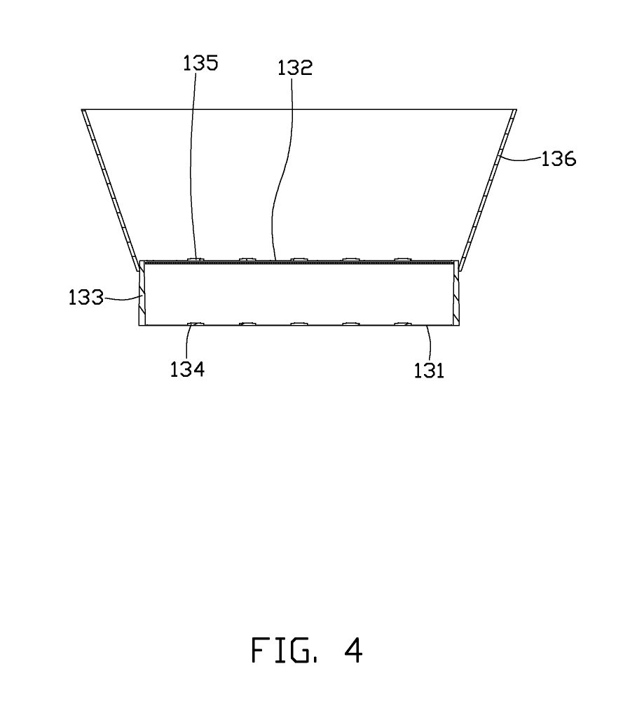

Referring to FIG. 4, the lamp body 130 comprises an annular third sidewall 133, a first substrate 131, and a second substrate 132 paralleled to the first substrate 131. The annular third sidewall 133 is made of transparent materials such as glass, polycarbonate, or polymethyl methacrylate. The annular third sidewall 133 has an outer diameter substantially the same as the diameter of the through hole 113 of the front cover 110. The annular third sidewall 133 has a height substantially equal to or less than a distance between the upper plate 111 and the bottom plate 121. The first substrate 131 is coupled to a bottom end of the annular third sidewall 133, and the second substrate 132 is coupled to a top end of the third sidewall 133. When assembled, the third sidewall 133 penetrates through the through hole 113 of the front cover 110, and is between the upper plate 111 and the bottom plate 121. A plurality of first LED units 134 are arranged on an upper surface of the first substrate 131 facing towards the second substrate 132. Light emitted by the plurality of first LED units 134 travels out of the LED lamp via the third sidewall 133 and the front cover 110, or via the third sidewall 133 and the first sidewall 112 and the second sidewall 122. A plurality of second LED units 135 are arranged on an upper surface of the second substrate 132 facing away from the first substrate 131. Light emitted from the plurality of second LED units 135 travels out of the LED lamp along a direction away from the first substrate 131. Conductive circuits are formed on surfaces of the first substrate 131 and the second substrate 132 to provide electric current for the plurality of first LED units 134 and the plurality of second LED units 135, respectively.

In the LED lamp 100 described above, the plurality to first LED units 134 are arranged between the first substrate 131 and the second substrate 132. Light from the plurality of first LED units 134 travels firstly through the annular third sidewall 133. Then, the light output from the annular third sidewall 133 will be reflected between the first reflective plate 114 and the second reflective plate 123, and finally travels outward from the first sidewall 112 and the second sidewall 122, or travels outward from a portion of the upper plate 111 uncovered by the first reflective plate 114.

In alternative embodiments, light scatter particles may be doped in the front cover 110. Therefore the light emitted from the first LED units 134 traveling through the front cover 110 may be further scattered by the light scatter particles. In addition, phosphor particles may also be doped in the front cover 110. The phosphor particles absorb light emitted from the first LED units 134 and emit a light with a wavelength different from the light emitted by the plurality of first LED units 134.

The lamp body 130 may further comprise a lampshade 136 surrounding the plurality of second LED units 135. The lampshade 136 has a funnel shape with gradually increasing diameters along a direction away from the plurality of second LED units 135 and the plurality of first LED units 134. The lampshade 136 is configured to concentrate the light emitted from the plurality of second LED units 135. In addition, a metallic reflective layer may be coated on an inner wall of the lampshade 136 to further concentrate the light emitted from the plurality of second LED units 135. The lampshade 136 may be made of a material selected from a group consisting of glass, polycarbonate, and polymethyl methacrylate.

The plurality of first LED units 134 and the plurality of second LED units 135 may be turned on or off independently. For example, if a relatively high light intensity in front of the LED lamp 100 is needed, only the plurality of second LED units 135 may be turned on, or the plurality of first LED units 134 and the plurality of second LED units 135 may be both turned on. Therefore, a position in front of the plurality of second LED units 135 is directly illuminated by the plurality of second LED units 135. In addition the position in front of the plurality of second LED units 135 may be indirectly illuminated the plurality of first LED unit. As a result, a light intensity in front of the LED lamp 100 is relatively high. If a relatively low light intensity in front of the LED lamp 100 is needed, only the plurality of first LED units 134 may be turned on. The light emitted from the plurality of first LED units 134 firstly travels through the annular third sidewall 133. Then the light is reflected between the first reflective plate 114 and the second reflective plate 123, and finally travels outward from the first sidewall 112 and the second sidewall 122. Therefore, a position in front of the plurality of first LED units 134 is indirectly illuminated by the plurality of first LED units 134 and a light intensity of in front of the LED lamp 100 is relatively low. By controlling the ON/OFF state of the plurality of first LED units 134 and the plurality of second LED units 135, different light intensity may be obtained in front of the LED lamp 100.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An LED lamp, comprising:
a front cover comprising an upper plate, and a first sidewall extending perpendicularly from the upper plate, and a through hole in a central portion of the upper plate;
a rear cover comprising a bottom plate, and a second sidewall extending perpendicularly from the bottom plate, the front cover and the rear cover are engaged together by the second sidewall sleeved on the first sidewall; and
a lamp body comprising a first substrate, a second substrate, and a third sidewall interconnecting the first substrate and the second substrate, the third sidewall penetrating through the through hole of the upper plate and is between the upper plate and the bottom plate;
a first LED unit on the first substrate, facing towards the second substrate; and
a second LED unit on the second substrate, facing away the first substrate, wherein
the LED lamp is configure to direct light from the first LED units out of the LED lamp via the third sidewall, and to direct light from the second LED units out of the LED lamp along a direction away from the first substrate.

2. The LED lamp of claim 1, wherein the first LED unit and the second LED unit can be turned on or off independently.

3. The LED lamp of claim 1, wherein a first reflective plate is formed on a bottom surface of the front cover facing towards the rear cover, and a second reflective plate is formed on an upper surface of the rear cover facing towards the front cover; wherein the LED lamp is further configured to reflect light from the first LED unit between the first reflective plate and the second reflective plate, and to direct light from the first LED unit out of the LED lamp through the third sidewall or through the first sidewall and second sidewall.

4. The LED lamp of claim 3, wherein the first reflective plate and the second reflective plate are coatings of metallic reflective layers.

5. The LED lamp of claim 4, wherein the metallic reflective layers are made of a material selected from a group consisting of Ag, Ni, Al, Cu, Au, and alloys thereof.

6. The LED lamp of claim 3, wherein the first reflective plate is annular and surrounds the through hole.

7. The LED lamp of claim 1, wherein the front cover is doped with light scattering particles to scatter light of the first LED unit passing through the front cover.

8. The LED lamp of claim 1, wherein the front cover is doped with phosphor particles, and the LED lamp is adapted to emit light of a different color.

9. The LED lamp of claim 1, further comprising a lampshade surrounding the second LED unit, the lampshade being configured to concentrate light from the second LED units.

10. The LED lamp of claim 9, wherein the lampshade is made of a material selected from a group consisting of glass, polycarbonate, and polymethyl methacrylate.

11. The LED lamp of claim 9, wherein the lampshade has a funnel shape with gradually increasing diameters along a direction away from the first LED unit and the second LED unit.

12. An LED lamp, comprising:
a front cover, a through hole in a central portion of the front cover;
a rear cover;
a lamp body penetrating through the through hole and is between the front cover and the rear cover; the lamp body comprising a first substrate, and a second substrate, a plurality of first LED units on a surface of the first substrate, a plurality of second LED units on a surface of the second substrate, wherein
the LED lamp is configured to direct light from the plurality of first LED units out of the LED lamp through a gap between the first substrate and the second substrate; and to direct light from the plurality of second LED units out of the LED lamp to an area in front of the plurality of second LED units.

13. The LED lamp of claim 12, wherein the plurality of first LED units and the plurality of second LED units can be turned on or off independently.

14. The LED lamp of claim 12, wherein a first reflective plate is formed on a bottom surface of the front cover facing towards the rear cover, and a second reflective plate is formed on an upper surface of the rear cover facing towards the front cover wherein the LED lamp is further configured to reflect light from the plurality of first LED units between the first reflective plate and the second reflective plate, and to direct light from the plurality of first LED units out of the LED lamp through the third sidewall or through the first sidewall and second sidewall.

15. The LED lamp of claim 14, wherein the first reflective plate and the second reflective plate are coating of metallic reflective layers.

16. The LED lamp of claim 15, wherein the metallic reflective layer is made of a material selected from a group consisting of Ag, Ni, Al, Cu, Au, and alloys thereof.

17. The LED lamp of claim 12, further comprising a lampshade surrounding the plurality of second LED units, the lampshade being configured for concentrating light from the plurality of second LED units to a direction in front of the plurality of second LED units.

18. The LED lamp of claim 17, wherein the lampshade is made of a material selected from a group consisting of glass, polycarbonate, and polymethyl methacrylate.

19. An LED lamp, comprising:
a housing comprising a front cover, and a rear cover coupled to the front cover, the front cover and the rear cover cooperatively defining a space in the housing, the front cover being transparent;
a substrate covering a central portion of the front cover, the substrate prevents light travel through the central portion;
a first LED unit received in the space of the housing and facing the front cover; and
a second LED unit on the substrate and facing an exterior of the housing.

20. The LED lamp of claim 19, wherein a through hole is defined in the central portion of the front cover, and the substrate couples to and seals the through hole of the front cover.
